(19) United States
(12) Patent Application Publication
(10) Pub. No.: US 2026/0096254 A1
(43) Pub. Date: Apr. 2, 2026

(54) SEMICONDUCTOR EPITAXIAL STRUCTURE AND SEMICONDUCTOR DEVICE

(71) Applicant: EPISTAR CORPORATION, Hsinchu (TW)

(72) Inventors: Yi-Chieh LIN, Hsinchu (TW); Shih-Chang Lee, Hsinchu (TW); Chia-Ming Liu, Hsinchu (TW)

(21) Appl. No.: 19/345,985

(22) Filed: Sep. 30, 2025

(30) Foreign Application Priority Data
Oct. 1, 2024 (TW) 113137560

(51) Int. Cl. H10H 20/84; H10H 20/816; H10H 29/24

(52) U.S. Cl. CPC H10H 20/84; H10H 20/816; H10H 29/24

(57) ABSTRACT

The present disclosure provides a semiconductor device including a first epitaxial stack and a first contact electrode. The first epitaxial stack includes a first semiconductor, a second semiconductor, and a first active region disposed between the first semiconductor structure and the second semiconductor structure. The first semiconductor structure includes a first capping layer having a first thickness. The second semiconductor structure includes a second capping layer having a second thickness larger than the first thickness. The first active region includes a light-emitting stack, a first confinement structure located between the light-emitting stack and the first capping layer, and a second confinement structure located between the light-emitting stack and the second capping layer. The first confinement structure has a third thickness, and the second confinement has a fourth thickness less than the third thickness. The first contact electrode is electrically connected to the first semiconductor structure.

### CROSS REFERENCE TO RELATED APPLICATIONS

This application claims the right of priority based on TW Application Serial No. 113137560, filed on Oct. 1, 2024, and the content of which is hereby incorporated by reference in its entirety.

### FIELD OF DISCLOSURE

The present disclosure relates to a semiconductor epitaxial structure and a semiconductor device, and more particularly to a semiconductor epitaxial structure applied to optoelectronic devices and a semiconductor device including the same.

### BACKGROUND OF THE DISCLOSURE

Semiconductor devices can be used in various fields such as lighting, medical care, display, communication, sensing, and power systems, and the development and research of related materials are also ongoing. For example, III-V group semiconductor materials containing a group III and a group V element can be applied to various optoelectronic semiconductor devices, such as light-emitting diodes (LEDs), laser diodes (LDs), photodetectors, or solar cells, as well as power devices such as switching elements or rectifiers. Generally, a light-emitting diode, which is one type of semiconductor light-emitting device, may include compound semiconductors including III-V group elements (such as gallium phosphide (GaP), gallium arsenide (GaAs), gallium nitride (GaN), etc.). Under the influence of an electric field, the light-emitting diode emits light through the recombination of electrons and holes in the active region. Light-emitting diodes have advantages such as low power consumption, fast response, small size, and long operating life, and are therefore widely used in various fields.

### SUMMARY OF THE DISCLOSURE

The present disclosure provides a semiconductor device, which includes a first epitaxial stack and a first contact electrode. The first epitaxial stack includes a first semiconductor, a second semiconductor, and a first active region. The first semiconductor structure includes a first capping layer having a first thickness. The second semiconductor structure includes a second capping layer having a second thickness. The first active region disposed between the first semiconductor structure and the second semiconductor structure. The first active region includes a light-emitting stack, a first confinement structure located between the light-emitting stack and the first capping layer, and a second confinement structure located between the light-emitting stack and the second capping layer. The first confinement structure has a third thickness, and the second confinement has a fourth thickness. The first contact electrode is electrically connected to the first semiconductor structure. The first thickness is smaller than the second thickness, and the third thickness is larger than the fourth thickness.

### BRIEF DESCRIPTION OF THE DRAWINGS

FIG. 1A shows a schematic cross-sectional view of a semiconductor epitaxial structure according to some embodiments of the present disclosure.

FIG. 1B shows an enlarged schematic view of region R in the semiconductor epitaxial structure shown in FIG. 1A.

FIG. 2 shows a schematic cross-sectional view of a semiconductor epitaxial structure according to some embodiments of the present disclosure.

FIG. 3A shows a schematic cross-sectional view of a semiconductor device according to some embodiments of the present disclosure.

FIG. 3B shows a schematic cross-sectional view of a semiconductor device according to some embodiments of the present disclosure.

FIG. 3C shows a schematic cross-sectional view of a semiconductor device according to some embodiments of the present disclosure.

FIG. 3D shows a schematic cross-sectional view of a semiconductor device according to some embodiments of the present disclosure.

FIG. 4A shows a top view schematic diagram of a semiconductor device according to some embodiments of the present disclosure.

FIG. 4B shows a schematic cross-sectional view of the semiconductor device along line A-A′ in FIG. 4A.

FIG. 5A shows a top view schematic diagram of a semiconductor device according to some embodiments of the present disclosure.

FIG. 5B shows a schematic cross-sectional view of the semiconductor device along line B-B′ in FIG. 5A.

FIG. 6A shows a top view schematic diagram of a semiconductor module according to some embodiments of the present disclosure.

FIG. 6B shows a schematic cross-sectional view of a semiconductor module according to some embodiments of the present disclosure.

### DETAILED DESCRIPTION OF THE DISCLOSURE

The following will provide a detailed explanation in conjunction with the drawings. It should be noted that the embodiments of the semiconductor device shown below are provided for illustrative purposes only and are not intended to limit the present disclosure to the following embodiments. In the drawings or the description, similar or identical components will be denoted by similar or identical reference numerals. Unless otherwise specified, the shapes or dimensions of the components in the drawings are merely illustrative and are not intended to be limiting. It should be particularly noted that components not described in the figures may be in forms known to those skilled in the art.

In the present disclosure, if not otherwise specified, the general formula InGaP represents Inₓ₀Ga₁₋ₓ₀P, wherein 0<x0<1; the general formula AlInP represents Alₓ₁In₁₋ₓ₁P, wherein 0<x1<1; the general formula InGaN represents Inₓ₂Ga₁₋ₓ₂N, wherein 0<x2<1; the general formula AlGaN represents Alₓ₃Ga₁₋ₓ₃N, wherein 0<x3<1; the general formula AlGaInP represents Alₓ₄Gaₓ₅In₁₋ₓ₄₋ₓ₅P, wherein 0<x4<1 and 0<x5<1; the general formula InGaAsP represents Inₓ₆Ga₁₋ₓ₆Asₓ₇P₁₋ₓ₇, wherein 0<x6<1□0<x7<1; the general formula AlGaInAs represents Alₓ₈Gaₓ₉In₁₋ₓ₈₋ₓ₉As, wherein 0<x8<1 and 0<x9<1; the general formula InGaNAs represents ₓ₁₀N₁₋ₓ₁₁, wherein 0<x10<1 and 0<x11<1; the general formula InGaAs represents Inₓ₁₂Ga₁₋ₓ₁₂As, wherein 0<x12<1; the general formula AlGaAs represents Alₓ₁₃Ga₁₋ₓ₁₃As, wherein 0<x13<1; the general formula AlInGaN represents Alₓ₁₄ Inₓ₁₅Ga₁₋ₓ₁₄₋ₓ₁₅As, wherein 0<x14<1 and 0<x15<1; the general formula AlGaAsP represents Alₓ₁₆Ga₁₋ₓ₁₆Asₓ₁₇ P₁₋ₓ₁₇, wherein 0<x16<1 and 0<x17<1. The content of each element may be adjusted for different purposes, such as for adjusting the energy gap, or the domain wavelength or peak wavelength when the semiconductor device is a light-emitting device.

The semiconductor device of the present disclosure is a light-emitting device (such as a light-emitting diode or a laser diode), a light absorbing device (such as a photo-detector) or a non-optoelectronic device. Analysis of the composition and/or dopant contained in each layer of the semiconductor device of the present disclosure may be conducted by any suitable method such as a secondary ion mass spectrometer (SIMS) or an energy dispersive X-ray spectrometer (EDX). A thickness of each layer may be obtained by any suitable method, such as a transmission electron microscopy (TEM) or a scanning electron microscope (SEM).

A person skilled in the art can realize that addition of other components based on a structure recited in the following embodiments is allowable. For example, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not physically contact each other. In addition, it should be realized that a positional relationship of a layer/structure may be altered when being observed in different orientations.

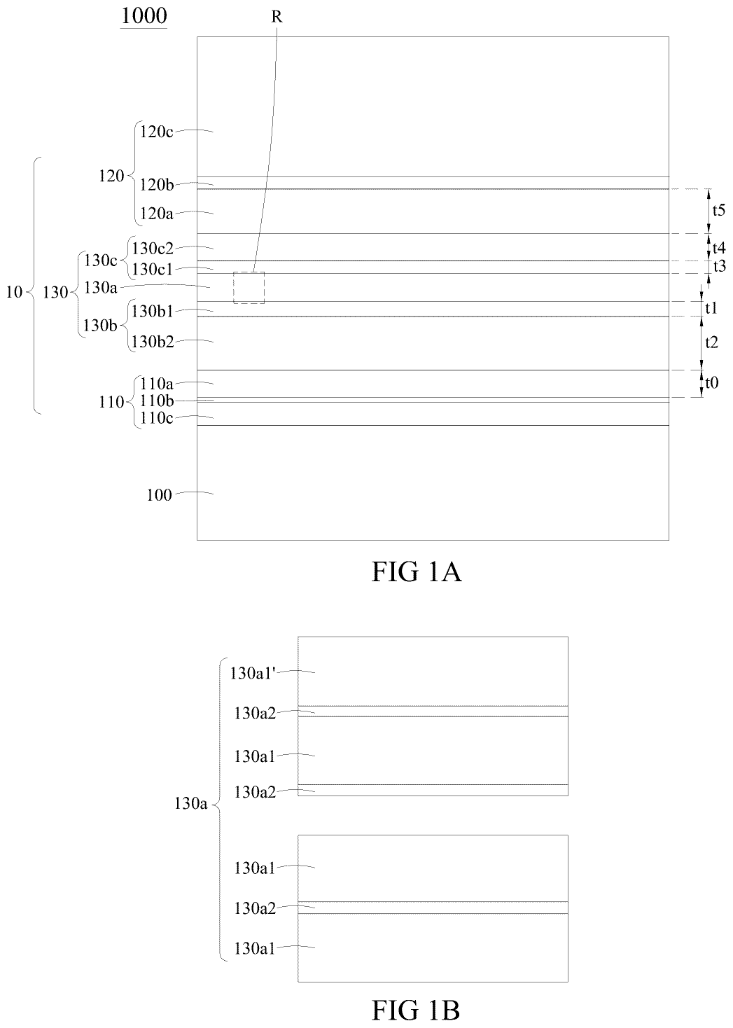

FIG. 1A shows a schematic cross-sectional view of a semiconductor epitaxial structure 1000 according to some embodiments of the present disclosure. FIG. 1B shows an enlarged schematic view of region R in the semiconductor epitaxial structure 1000 shown in FIG. 1A. As shown in FIG. 1A, the semiconductor epitaxial structure 1000 includes a first epitaxial stack 10. The first epitaxial stack 10 includes a first semiconductor structure 110, a second semiconductor structure 120, and a first active region 130. The first active region 130 is located between the first semiconductor structure 110 and the second semiconductor structure 120. The first semiconductor structure 110 and the second semiconductor structure 120 may have different conductivity types to respectively provide electrons and holes, or holes and electrons. For example, each layer in the first semiconductor structure 110 may be of n-type and each layer in the second semiconductor structure 120 may be of p-type, or vice versa, with each layer in the first semiconductor structure 110 being p-type and each layer in the second semiconductor structure 120 being n-type. Electrons and holes may recombine in the first active region 130 to emit light of a specific wavelength. The emitted light may include visible or invisible light. The conductivity types of the layers in the first semiconductor structure 110 and the second semiconductor structure 120 can be adjusted by adding different dopants. The dopants may include elements from group II, group IV, or group VI of the periodic table, such as magnesium (Mg), zinc (Zn), carbon (C), silicon (Si), or tellurium (Te), among others.

According to some embodiments, the first epitaxial stack 10 may has a thickness ranging from 1 μm to 5 μm for being applicable for fabricating semiconductor devices with miniaturization requirements (for example the semiconductor device has a length or width of less than 50 μm). The semiconductor epitaxial structure 1000 may optionally further include a substrate 100. The first epitaxial stack 10 may be formed on the substrate 100. As shown in FIG. 1A, the substrate 100 is located below the first semiconductor structure 110, the second semiconductor structure 120, and the first active region 130. In this embodiment, the substrate 100 is a growth substrate used for epitaxial growth, such as a sapphire, gallium arsenide (GaAs), indium phosphide (InP), or gallium phosphide (GaP).

The semiconductor epitaxial structure 1000 may include a double heterostructure (DH), double-side double heterostructure (DDH), or multiple quantum wells (MQW) structure. The layers in the first semiconductor structure 110, the second semiconductor structure 120, and the first active region 130 may respectively include III-V semiconductor materials. The III-V semiconductor materials may include elements such as aluminum (Al), gallium (Ga), arsenic (As), phosphorus (P), or indium (In). In some embodiments, the first semiconductor structure 110, the first active region 130, and the second semiconductor structure 120 may be free of nitrogen (N). The III-V semiconductor materials may be binary compound semiconductors (such as GaAs, GaP, or GaN), ternary compound semiconductors (such as InGaAs, AlGaAs, InGaP, AlInP, InGaN, or AlGaN), or quaternary compound semiconductors (such as AlGaInAs, AlGaInP, AlInGaN, InGaAsP, InGaNAs, or AlGaAsP). The light emitted by the first active region 130 depends on the material composition of the first active region 130. For example, when the material of the first active region 130 includes AlGaN, it may emit ultraviolet light with a peak wavelength of 250 nm to 400 nm; when the material includes InGaN, it may emit deep blue or blue light with a peak wavelength of 400 nm to 490 nm, green or yellow light with a peak wavelength of 490 nm to 550 nm, or red light with a peak wavelength of 560 nm to 650 nm; when the material includes InGaP or AlGaInP, it may emit yellow, orange, or red light with a peak wavelength of 530 nm to 700 nm; when the material includes InGaAs, InGaAsP, AlGaAs, or AlGaInAs, it may emit infrared light with a peak wavelength of 700 nm to 1700 nm.

The first semiconductor structure 110 and the second semiconductor structure 120 may each be a single-layer or multi-layer structure. As shown in FIG. 1A, the first semiconductor structure 110 may include a first capping layer 110a and a first contact layer 110c. The second semiconductor structure 120 may include a second capping layer 120a and a second contact layer 120c. The first capping layer 110a and the second capping layer 120a are adjacent to the first active region 130. In some embodiments, the first capping layer 110a and the second capping layer 120a may have different conductivity types and can respectively provide electrons and holes. In some embodiments, the thickness t0 of the first capping layer 110a may be greater than or equal to 100 Å and less than 1000 Å, such as, in the range of 100 Å to 200 Å, 400 Å, 600 Å, or 800 Å. According to some embodiments, when the thickness t0 of the first capping layer 110a is adjusted to be greater than or equal to 100 Å and less than 1000 Å, the probability of carrier recombination at the sidewall can be reduced, thereby increasing the light emission intensity. In some embodiments, when the thickness t0 of the first capping layer 110a is less than 100 Å, the carrier confinement capability of the first capping layer 110a may be too low, affecting brightness; when the thickness t0 of the first capping layer 110a is greater than or equal to 1000 Å, carriers in the first capping layer 110a may more easily migrate to the sidewall, increasing the probability of sidewall recombination and thus affecting brightness. According to some embodiments, since the mobility of n-type carriers is greater than that of p-type carriers, when the first capping layer 110a is n-type, adjusting the thickness t0 of the first capping layer 110a to be greater than or equal to 100 Å and less than 1000 Å can effectively reduce the current to diffuse in the first capping layer 110a, and improve the light emission efficiency of the semiconductor epitaxial structure 1000 under low current (such as, below 20 mA).

In some embodiments, the first capping layer 110a contains aluminum (Al). The aluminum content percentage in the first capping layer 110a may be greater than 50%. In some embodiments, the aluminum content percentage in the first capping layer 110a is greater than or equal to 54%, such as, in the range of 54% to 60%. According to some embodiments, by making the aluminum content percentage in the first capping layer 110a greater than or equal to 54%, the carrier confinement capability of the first capping layer 110a can be improved, which helps to further enhance brightness. The aluminum content percentage may be obtained by analyzing the first capping layer 110a using EDX or SIMS. For example, when the first capping layer 110a includes Al_{z1}Ga_{z2}In_{1-z1-z2}P (0<z1≤1 and 0≤z2<1), the analysis results can yield z1 and z2 (atom %). Here, the aluminum content percentage of the first capping layer 110a can be defined as z1*100%. That is, the aluminum content percentage represents the atomic percentage of Al in relation to the total atomic percentage of all group III elements. In some embodiments, the first capping layer 110a may include a ternary III-V compound semiconductor, such as Al_{z1}In_{1-z1}P. In some embodiments, 0.5<z1<0.6. In some embodiments, the second capping layer 120a contains aluminum (Al). The aluminum content percentage in the second capping layer 120a may be less than that in the first capping layer 110a. The aluminum content percentage in the second capping layer 120a may be less than or equal to 50%. In some embodiments, the second capping layer 120a may include a ternary III-V compound semiconductor, such as Al_{z3}In_{1-z3}P. In some embodiments, 0<z3≤0.5. In some embodiments, the thickness ratio of the first capping layer 110a (t0) to the second capping layer 120a (t5) may range from 1:5 to 1:20.

The first contact layer 110c and the second contact layer 120c are used to form good contact (ohmic contact) with a metal. According to some embodiments, the first contact layer 110c and the second contact layer 120c may include different materials, for example, the first contact layer 110c may include arsenides and the contact layer 120c may include phosphides, or vice versa.. In some embodiments, the first contact layer 110c and the second contact layer 120c include binary III-V semiconductor materials. For example, the first contact layer 110c includes GaAs and the second contact layer 120c includes GaP, or vice versa. In some embodiments, the first capping layer 110a may include a first dopant, and the first contact layer 110c includes a second dopant different from the first dopant. In some embodiments, the second capping layer 120a may include a third dopant, and the second contact layer 120c includes a fourth dopant different from the third dopant. The first dopant, second dopant, third dopant, and fourth dopant may all be different. For example, the first and second dopants may be selected from silicon (Si) or tellurium (Te), and the third and fourth dopants may be selected from magnesium (Mg) or carbon (C). According to some embodiments, the concentration of the second dopant in the first contact layer 110c may be greater than the concentration of the first dopant in the first capping layer 110a. For example, the concentration of the first dopant in the first capping layer 110a may be in the range of 1×10¹⁷cm⁻³ to 2×10¹⁸cm⁻³. The concentration of the second dopant in the first contact layer 110c may be in the range of 1×10¹⁸cm⁻³ to 1×10¹⁹cm⁻³. According to some embodiments, the concentration of the fourth dopant in the second contact layer 120c may be greater than the concentration of the third dopant in the second capping layer 120a. For example, the concentration of the third dopant in the second capping layer 120a may be in the range of 1×10¹⁷cm⁻³ to 2×10¹⁸cm⁻³. The concentration of the fourth dopant in the second contact layer 120c may be in the range of 2×10¹⁹cm⁻³ to 8×10²⁰cm⁻³.

As shown in FIG. 1A, the first active region 130 may include a first light-emitting stack 130a, a first confinement structure 130b, and a second confinement structure 130c. The first light-emitting stack 130a is a first active stack. The first light-emitting stack 130a may include N pairs of alternately stacked barrier layers 130a1 and well layers 130a2, and N is a positive integer greater than or equal to 1 and less than or equal to 6. As shown in FIG. 1B, the first light-emitting stack 130a may further optionally include an additional barrier layer 130a1′, which is adjacent to the well layer 130a2 of the Nth pair of barrier layers 130a1 and well layers 130a2. The first confinement structure 130b and the second confinement structure 130c may each be a single-layer or a multi-layer structure.

As shown in FIG. 1A, the first confinement structure 130b may include a first sublayer 130b1 and a second sublayer 130b2. The first sublayer 130b1 is located between the second sublayer 130b2 and the first light-emitting stack 130a. In this embodiment, the second confinement structure 130c may include a third sublayer 130c1 and a fourth sublayer 130c2. The third sublayer 130c1 is located between the fourth sublayer 130c2 and the first light-emitting stack 130a. The first sublayer 130b1 and the second sublayer 130b2 may contain aluminum (Al). In some embodiments, the aluminum content percentage in the first sublayer 130b1 is less than that in the second sublayer 130b2 . The third sublayer 130c1 and the fourth sublayer 130c2 may also contain aluminum (Al). In some embodiments, the aluminum content percentage in the third sublayer 130c1 is less than that in the fourth sublayer 130c2. The first sublayer 130b1 and the second sublayer 130b2 may include different materials, and the third sublayer 130c1 and the fourth sublayer 130c2 may contain different materials. The first sublayer 130b1, the second sublayer 130b2, the third sublayer 130c1, and the fourth sublayer 130c2 may include ternary or quaternary III-V compound semiconductors, such as AlInP or AlGaInP.

According to some embodiments, the first sublayer 130b1 and the third sublayer 130c1 include Al_{z4}Ga_{z5}In_{1-z4-z5}P, and the second sublayer 130b2 and the fourth sublayer 130c2 include Al_{z6}In_{1-z6}P. In some embodiments, 0.3≤z4≤0.4 and 0.1≤z5≤0.2. In some embodiments, 0.4≤z6≤0.5. In some embodiments, the first light-emitting stack 130a, the first confinement structure 130b, and/or the second confinement structure 130c may also contain a first dopant, a second dopant, a third dopant, or a fourth dopant, with a concentration, such as, less than or equal to 2×10¹⁷cm⁻³. Specifically, during the epitaxial growth of the first active region 130, dopant doping is not performed, and the dopants present in the first active region 130 may be diffused from the first capping layer 110a or the second capping layer 120a into the first light-emitting stack 130a, the first confinement structure 130b, and/or the second confinement structure 130c.

As shown in FIG. 1A, the first sublayer 130b1, the second sublayer 130b2, the third sublayer 130c1, and the fourth sublayer 130c2 may respectively have a first thickness t1, a second thickness t2, a third thickness t3, and a fourth thickness t4. The second thickness t2 may be greater than the first thickness t1. The fourth thickness t4 may be greater than the third thickness t3. The second thickness t2 may be greater than the first thickness t1, the third thickness t3, and the fourth thickness t4, thereby further reducing the diffusion of the first dopant from the first capping layer 110a into the first light-emitting stack 130a, which is beneficial for enhancing brightness. According to some embodiments, the second thickness t2 may be in the range of 1000 Å to 3000 Å, and the first thickness t1, third thickness t3, and fourth thickness t4 may be in the range of 300 Å to 600 Å. According to some embodiments, the first confinement structure 130b and the second confinement structure 130c may also be a single-layer structure, for example, the first confinement structure 130b includes the second sublayer 130b2 and does not include the first sublayer 130b1, and the second confinement structure 130c includes the fourth sublayer 130c2 and does not include the third sublayer 130c1.

The first semiconductor structure 110 may optionally further include a first transition structure 110b, which is located between the first capping layer 110a and the first contact layer 110c. The first transition structure 110b may be in direct contact with both the first contact layer 110c and the first capping layer 110a. According to some embodiments, when there is a lattice mismatch between the first contact layer 110c and the first capping layer 110a, the first transition structure 110b can reduce stress to stabilize the structure. According to some embodiments, the first transition structure 110b may include a quaternary III-V compound semiconductor material (such as AlGaInP). According to some embodiments, the first transition structure 110b may include a second dopant. The concentration of the second dopant in the first transition structure 110b may be, in the range of 1×10¹⁸cm⁻³ to 5×10¹⁸cm⁻³. The second semiconductor structure 120 may optionally further include a second transition structure 120b, which is located between the second capping layer 120a and the second contact layer 120c. The second transition structure 120b may be in direct contact with both the second capping layer 120a and the second contact layer 120c. According to some embodiments, when there is a lattice mismatch between the second capping layer 120a and the second contact layer 120c, the second transition structure 120b can reduce stress to stabilize the structure. According to some embodiments, the second transition structure 120b may include a ternary or quaternary III-V compound semiconductor material (such as AlInP or AlGaInP). According to some embodiments, the second transition structure 120b may include a first dopant and a third dopant, and the concentration of the third dopant in the second transition structure 120b is greater than that of the first dopant. For example, the concentration of the third dopant in the second transition structure 120b may be in the range of 1×10¹⁸cm⁻³ to 5×10¹⁸cm⁻³, while the concentration of the first dopant may be in the range of 5×10¹⁶cm⁻³ to 5×10¹⁷cm⁻³.

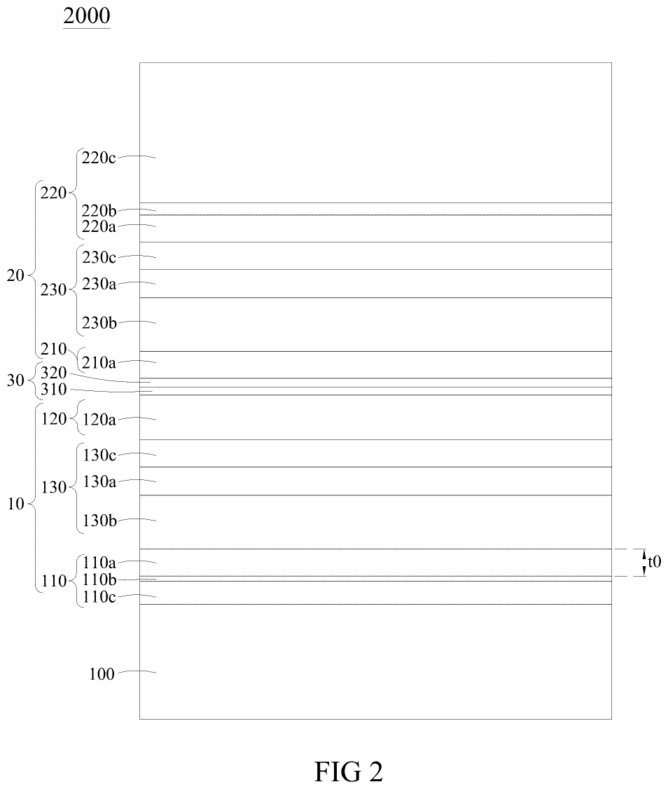

FIG. 2 shows a schematic cross-sectional view of a semiconductor epitaxial structure 2000 according to some embodiments of the present disclosure. The difference between the semiconductor epitaxial structure 2000 and the semiconductor epitaxial structure 1000 is that the semiconductor epitaxial structure 2000 further includes a second epitaxial stack 20 and a tunneling structure 30. The tunneling structure 30 is disposed between the first epitaxial stack 10 and the second epitaxial stack 20. In this embodiment, the first epitaxial stack 10 in the semiconductor epitaxial structure 2000 may not include the second transition structure 120b and the second contact layer 120c. As shown in FIG. 2, the second epitaxial stack 20 includes a third semiconductor structure 210, a fourth semiconductor structure 220, and a second active region 230. The second active region 230 is located between the third semiconductor structure 210 and the fourth semiconductor structure 220. In this embodiment, the third semiconductor structure 210 may include a third capping layer 210a. The fourth semiconductor structure 220 may include a fourth capping layer 220a and a third contact layer 220c. The fourth semiconductor structure 220 may further optionally include a third transition structure 220b, which is disposed between the fourth capping layer 220a and the third contact layer 220c. The third transition structure 220b may be in direct contact with both the fourth capping layer 220a and the third contact layer 220c. The third capping layer 210a and the fourth capping layer 220a may be adjacent to the tunneling structure 30.

The third capping layer 210a and the first capping layer 110a may have the same conductivity type. In some embodiments, the third capping layer 210a may include a fifth dopant, which may be the same as or different from the first dopant, and may also be the same as or different from the second dopant. For example, the concentration of the fifth dopant in the third capping layer 210a may be in the range of 1×10¹⁸cm⁻³ to w 1×10¹⁹cm⁻³. The fourth capping layer 220a and the third contact layer 220c may have the same conductivity type as the second capping layer 120a. In some embodiments, the fourth capping layer 220a may include a sixth dopant, which may be the same as or different from the third dopant. For example, the concentration of the sixth dopant in the fourth capping layer 220a may be in the range of 1×10¹⁷cm⁻³ to 2×10¹⁸cm⁻³. In some embodiments, the third contact layer 220c may include a seventh dopant, which may be the same as or different from the fourth dopant. For example, the concentration of the seventh dopant in the third contact layer 220c may be in the range of 2×10¹⁹cm⁻³ to 8×10²⁰cm⁻³.

The third transition structure 220b may be referred to the above description of the second transition structure 120b. The second active region 230 may include a second light-emitting stack 230a, a third confinement structure 230b, and a fourth confinement structure 230c. The second light-emitting stack 230a, the third confinement structure 230b, and the fourth confinement structure 230c may be referred to the above descriptions of the first light-emitting stack 130a, the first confinement structure 130b, and the second confinement structure 130c, respectively. The second light-emitting stack 230a is a second active stack. The light emitted from the first active region 130 and the second active region 230 may have the same or different peak wavelengths. In some embodiments, the first active region 130 and the second active region 230 may emit light of different peak wavelengths but belonging to the same color. For example, both the first active region 130 and the second active region 230 may emit red light with a peak wavelength in the range of 560 nm to 650 nm, but the peak wavelengths of the two are not equal.

The tunneling structure 30 may include a first tunneling layer 310 and a second tunneling layer 320. In this embodiment, the first tunneling layer 310 is adjacent to the second capping layer 120a, and the second tunneling layer 320 is adjacent to the third capping layer 210a. According to some embodiments, the aluminum content percentage in the first tunneling layer 310 is greater than that in the second tunneling layer 320. The aluminum content percentage in the first tunneling layer 310 may be greater than 50%, such as, in the range of 55% to 60%. The aluminum content percentage in the second tunneling layer 320 may be less than 40%, such as, in the range of 0% to 30%. According to some embodiments, the aluminum content percentage in the second tunneling layer 320 is greater than 5%, such as, in the range of 10% to 15%, which can further enhance brightness performance. The first tunneling layer 310 and the second tunneling layer 320 may respectively be arsenides or phosphides. Specifically, the first tunneling layer 310 may include a ternary III-V compound semiconductor material (such as AlGaAs). The second tunneling layer 320 may include a ternary or quaternary III-V compound semiconductor material (such as AlGaInP or InGaP). According to some embodiments, the first tunneling layer 310 includes Al_{z7}Ga_{1-z7}As. In some embodiments, 0.5<z7≤0.6. According to some embodiments, the second tunneling layer 320 includes Al_{z8}Ga_{z9}In_{1-z8-z9}P. In some embodiments, 0≤z8≤0.2, 0 <z9≤0.5. In some embodiments, the bandgap of the first tunneling layer 310 and the bandgap of the second tunneling layer 320 are greater than the bandgap of the well layer 130a2 in the first active region 130 and greater than the bandgap of the well layer 130a2 in the second active region 230. Accordingly, it is possible to prevent the tunneling structure 30 from absorbing light emitted by the first active region 130 and the second active region 230, thereby affecting light emission efficiency. The first tunneling layer 310 and the second tunneling layer 320 may have different conductivity types; for example, the first tunneling layer 310 may be p-type and the second tunneling layer 320 may be n-type. In some embodiments, the first tunneling layer 310 may include a fourth dopant, and the second tunneling layer 320 may include a first dopant. The concentration of the fourth dopant in the first tunneling layer 310 may be greater than the concentration of the first dopant in the second tunneling layer 320. For example, the concentration of the fourth dopant in the first tunneling layer 310 may be in the range of 5×10¹⁹cm⁻³ to 5×10²⁰cm⁻³. The concentration of the first dopant in the second tunneling layer 320 may be in the range of 1×10¹⁹cm⁻³ to 1×10²⁰cm⁻³.

In this embodiment, since the semiconductor epitaxial structure 2000 includes two light-emitting stacks and may further be combined with an improved tunneling structure 30, brightness performance can be further enhanced and the cost per unit brightness can be effectively reduced. According to some embodiments, the first epitaxial stack 10, the second epitaxial stack 20, and the tunneling structure 30 may have the total thickness be in the range of 3 μm to 8 μm for being applicable for fabricating semiconductor devices with miniaturization requirements. Detailed descriptions regarding the positions, relative relationships, material compositions, and structural variations of each layer or structure in this embodiment have already been provided in the foregoing embodiments and will not be repeated here.

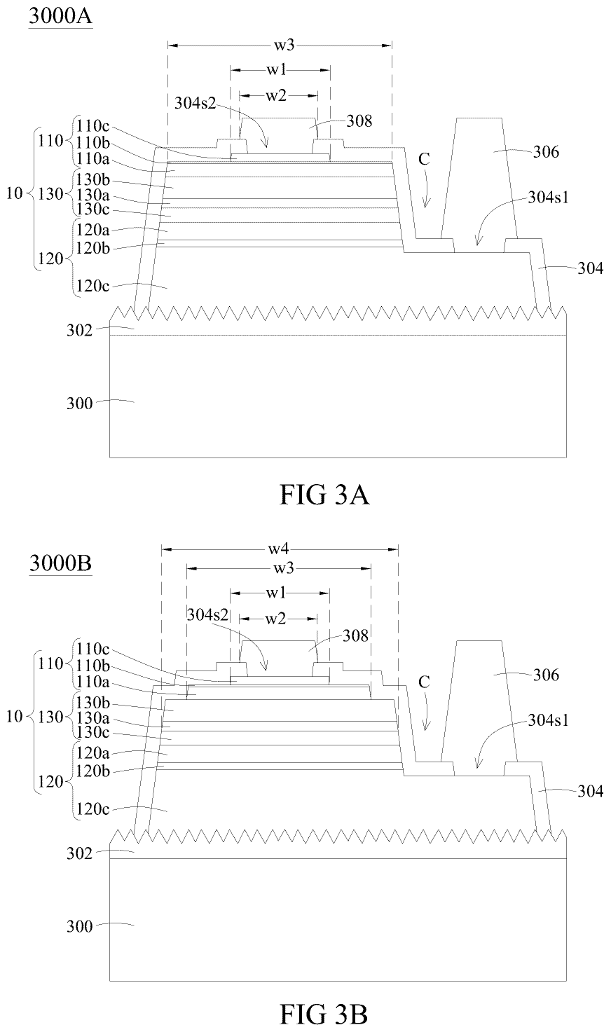

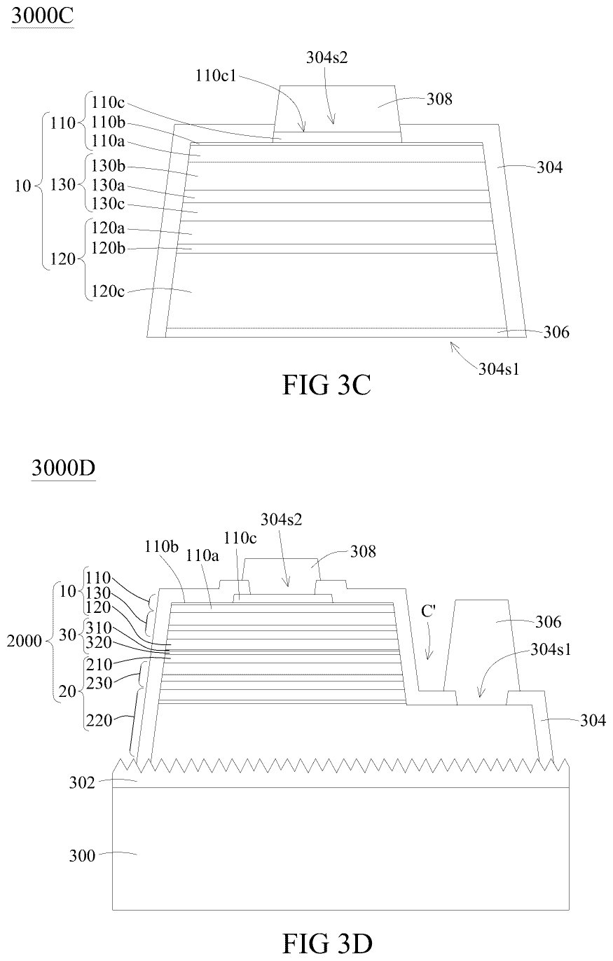

Specifically, the semiconductor epitaxial structures 1000 and 2000 may be applied to the fabrication of semiconductor devices and semiconductor modules. In FIGS. 3A to 6B, exemplary descriptions of the structures of semiconductor devices and semiconductor modules are provided. FIG. 3A is a schematic cross-sectional view of a semiconductor device 3000A according to some embodiments of the present disclosure. The semiconductor device 3000A may include the semiconductor epitaxial structure 1000. As shown in FIG. 3A, the semiconductor device 3000A includes a first epitaxial stack 10, a first contact electrode 308, and a second contact electrode 306. The first epitaxial stack 10 includes a first semiconductor structure 110, a second semiconductor structure 120, and a first active region 130. In this embodiment, the first epitaxial stack 10 has a recess C. The recess C may be formed, for example, by removing a portion of the first semiconductor structure 110, the second semiconductor structure 120, and the first active region 130 using wet etching or dry etching. The bottom of the recess C may be composed of the second contact layer 120c.

As shown in FIG. 3A, the first contact electrode 308 is located on and in direct contact with the first contact layer 110c. The second contact electrode 306 is located on and in direct contact with the second contact layer 120c. From a top view, the second contact electrode 306 and the first contact electrode 308 may be circular, oval, rectangular, or other polygonal shapes. In this embodiment, the first contact layer 110c may be a patterned semiconductor layer. As shown in FIG. 3A, the first contact layer 110c may have a width w1, where the width w1 is greater than or equal to the width w2 of the first contact electrode 308 and less than the width w3 of the first capping layer 110a. According to some embodiments, if the first contact layer 110c absorbs light emitted from the first active region 130, patterning the first contact layer 110c can reduce the absorption of light from the first active region 130 by the first contact layer 110c, thereby enhancing the light emission intensity of the semiconductor device.

The semiconductor device 3000A further includes an insulating structure 304 covering the epitaxial structure 10. In this embodiment, the insulating structure 304 may have a first opening 304s1 and a second opening 304s2, respectively corresponding to the second contact electrode 306 and the first contact electrode 308. The insulating structure 304 can provide insulation, protection, and/or reflection functions, such as isolating external moisture or contaminants to prevent damage to the first active region 130 in the epitaxial structure 10 and to avoid leakage paths in the device. The insulating structure 304 may have a single-layer or multi-layer structure and may include dielectric materials, such as oxides, nitrides, polymers, or combinations thereof. The oxides may include aluminum oxide (AlOx), silicon oxide (SiOx), titanium oxide (TiOx), niobium pentoxide (Nb₂O₅), or tantalum pentoxide (Ta₂O₅). The nitrides may include aluminum nitride (AlN) or silicon nitride (SiNx). The polymers may include polyimide or benzocyclobutene (BCB). In some embodiments, the insulating structure 304 may further have a reflective function, such as including a distributed Bragg reflector (DBR). The distributed Bragg reflector may include a plurality of first dielectric layers and a plurality of second dielectric layers (not shown) alternating on each other. The first dielectric layer and the second dielectric layer have different refractive indices. The first and second dielectric layers may include silicon dioxide (SiO₂), titanium dioxide (TiO₂), or niobium pentoxide (Nb₂O₅). For example, combinations of the first and second dielectric layers may be SiO₂/TiO₂ or SiO₂/Nb₂O₅. By providing the insulating structure 304 with a reflective function, light emitted from the first active region 130 can primarily be emitted from the side of the second semiconductor structure 120.

According to some embodiments, the materials of the second contact electrode 306 and the first contact electrode 308 may include conductive oxides, metals, or alloys. Examples of conductive oxides may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium zinc oxide (IZO), or combinations thereof. Examples of metals may include germanium (Ge), beryllium (Be), zinc (Zn), gold (Au), nickel (Ni), or copper (Cu). Alloys may include at least two of the above metals, such as, germanium-gold-nickel (GeAuNi), beryllium-gold (BeAu), germanium-gold (GeAu), or zinc-gold (ZnAu). The material of the second contact electrode 306 and the material of the first contact electrode 308 may be different or the same. According to some embodiments, the second contact electrode 306 includes beryllium-gold (BeAu), and the first contact electrode 308 includes germanium-gold (GeAu). The semiconductor device 3000A may further optionally include a bonding substrate 300 and a bonding structure 302. The bonding substrate 300 is disposed below the first epitaxial stack 10, and the bonding structure 302 is disposed between the bonding substrate 300 and the first epitaxial stack 10 to connect the two. In this embodiment, the second contact layer 120c may serve as the thickest layer of the second semiconductor structure 120 and may provide the required carriers (such as electrons), structural support, current spreading, and contact characteristics.

In some embodiments, a method for manufacturing the semiconductor device 3000A may include the following steps: providing the semiconductor epitaxial structure 1000; bonding the second semiconductor structure 120 to the bonding substrate 300 by means of the bonding structure 302; removing the substrate 100 of the semiconductor epitaxial structure 1000; removing a portion of the first semiconductor structure 110, the second semiconductor structure 120, and the first active region 130 to form the recess C; forming the second contact electrode 306 in the recess C; and forming the first contact electrode 308 on the first contact layer 110c. In some embodiments, the method for manufacturing the semiconductor device 3000A may further optionally include removing the bonding substrate 300 and the bonding structure 302 after forming the second contact electrode 306 and the first contact electrode 308. Detailed descriptions regarding the positions, relative relationships, material compositions, and structural variations of each layer or structure in this embodiment have already been provided in the foregoing embodiments and will not be repeated here.

FIG. 3B shows a schematic cross-sectional view of a semiconductor device 3000B according to some embodiments of the present disclosure. The difference between semiconductor device 3000B and semiconductor device 3000A is that the first capping layer 110a of semiconductor device 3000B may be a patterned semiconductor layer. As shown in FIG. 3B, the width w3 of the first capping layer 110a may be greater than the width w1 of the first contact layer 110c and less than the width w4 of the first confinement structure 130b. The area of the first capping layer 110a may be between the area of the first contact layer 110c and the area of the first confinement structure 130b. According to some embodiments, by adjusting the width/area of the first capping layer 110a within the above range, carriers are less likely to diffuse to the sidewalls of the epitaxial structure, thereby reducing sidewall recombination and improving the light emission intensity of the device. Detailed descriptions regarding the positions, relative relationships, material compositions, and structural variations of each layer or structure in this embodiment have already been provided in the foregoing embodiments and will not be repeated here.

FIG. 3C shows a schematic cross-sectional view of a semiconductor device 3000C according to some embodiments of the present disclosure. The semiconductor device 3000C may include the semiconductor epitaxial structure 1000. As shown in FIG. 3C, the semiconductor device 3000C includes a first epitaxial stack 10, a second contact electrode 306, and a first contact electrode 308. In this embodiment, unlike semiconductor devices 3000A and 3000B, the second contact electrode 306 and the first contact electrode 308 are located on different sides of the second contact layer 120c, that is, the semiconductor device 3000C is a vertical device. In semiconductor devices 3000A and 3000B, the second contact electrode 306 and the first contact electrode 308 are located on the same side of the second contact layer 120c, that is, semiconductor devices 3000A and 3000B are lateral devices. The second contact electrode 306 may be in direct contact with the second contact layer 120c, while the first contact electrode 308 may be in direct contact with the first contact layer 110c, for example, covering the geometric center of the upper surface 110c1 of the first contact layer 110c.

As shown in FIG. 3C, the second contact electrode 306 and the first contact electrode 308 overlap in a vertical direction. In some embodiments, one of the second contact electrode 306 and the first contact electrode 308 may include a conductive oxide. For example, the second contact electrode 306 may include a conductive oxide, while the first contact electrode 308 may include a metal or alloy. According to some embodiments, when the second contact electrode 306 includes a conductive oxide (such as ITO), the second contact electrode 306 can be transparent to light emitted from the first active region 130, and when the semiconductor device 3000C operates, the light emitted from the first active region 130 can be emitted through the second contact electrode 306. In other embodiments, the semiconductor device 3000C may also include the semiconductor epitaxial structure 2000, and the second contact electrode 306 may be in direct contact with the third contact layer 220c, while the first contact electrode 308 may be in direct contact with the first contact layer 110c. Detailed descriptions regarding the positions, compositions, and materials of the layers or structures in this embodiment have already been provided in the foregoing embodiments and will not be repeated here.

FIG. 3D shows a schematic cross-sectional view of a semiconductor device 3000D according to some embodiments of the present disclosure. The semiconductor device 3000D may include the semiconductor epitaxial structure 2000. The difference between semiconductor device 3000D and semiconductor device 3000A is that semiconductor device 3000D further includes a second epitaxial stack 20 and a tunneling structure 30. Specifically, in this embodiment, the semiconductor epitaxial structure 2000 has a recess C′. The recess C′ may be formed, for example, by removing a portion of the first semiconductor structure 110, the second semiconductor structure 120, the first active region 130, the tunneling structure 30, the third semiconductor structure 210, the fourth semiconductor structure 220, and the second active region 230 by wet or dry etching. As shown in FIG. 3D, the second contact electrode 306 is disposed on and in direct contact with the third contact layer 220c. The first contact electrode 308 is disposed on and in direct contact with the first contact layer 110c. The semiconductor device 3000D may further optionally include a bonding substrate 300 and a bonding structure 302. According to some embodiments, the first contact layer 110c and/or the first capping layer 110a in the semiconductor device 3000D may also be a patterned semiconductor layer, and specific reference may be made to the relevant descriptions of semiconductor devices 3000A and 3000B above. Detailed descriptions regarding the positions, compositions, and materials of the layers or structures in this embodiment have already been provided in the foregoing embodiments and will not be repeated here.

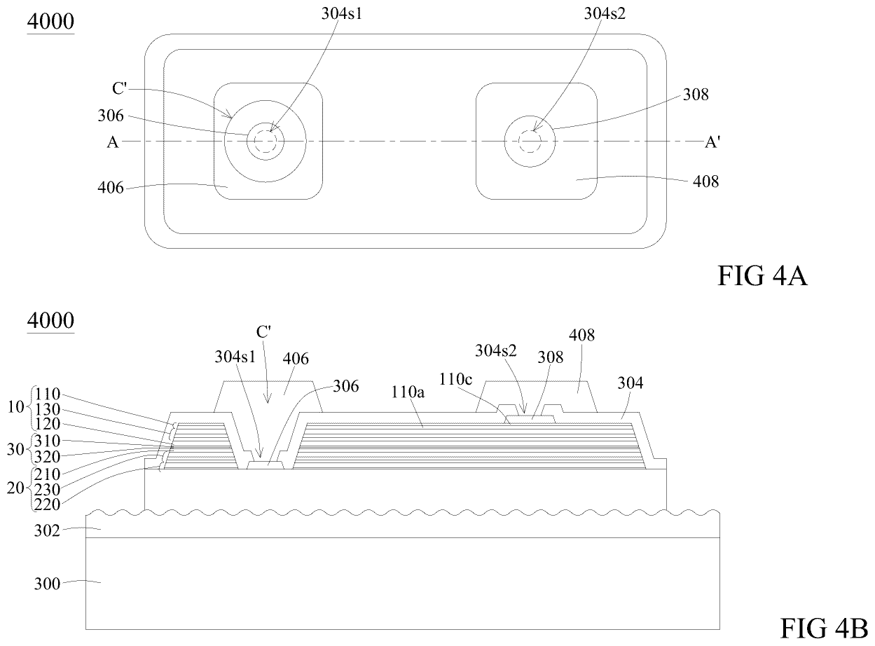

FIG. 4A shows a top view schematic diagram of a semiconductor device 4000 according to some embodiments of the present disclosure. FIG. 4B is a schematic cross-sectional view of the semiconductor device 4000 of FIG. 4A taken along line A-A′. The difference between semiconductor device 4000 and semiconductor device 3000D is that the recess C′ in semiconductor device 4000 is located within the interior of the semiconductor epitaxial structure 2000, whereas the recess C′ in semiconductor device 3000D is located at the edge of the semiconductor epitaxial structure 2000. As shown in FIG. 4A, from a top view, the contour of the recess C′ forms a closed shape, such as a circle, oval, rectangle, or other polygon. In addition, the semiconductor device 4000 further includes a first electrode pad 406 and a second electrode pad 408. As shown in FIGS. 4A and 4B, in this embodiment, the insulating structure 304 covers a portion of the second contact electrode 306 and the first contact electrode 308. The first electrode pad 406 fills the recess C′ and the first opening 304s1, and is in direct contact with the second contact electrode 306 to form an electrical connection. The second electrode pad 408 fills the second opening 304s2 and is in direct contact with the first contact electrode 308 to form an electrical connection. The first electrode pad 406 and the second electrode pad 408 may include metallic materials, such as nickel (Ni), titanium (Ti), platinum (Pt), palladium (Pd), silver (Ag), gold (Au), aluminum (Al), tin (Sn), copper (Cu), bismuth (Bi), indium (In), or combinations thereof.

In some embodiments, the upper surface of the first electrode pad 406 and the upper surface of the second electrode pad 408 may have substantially the same height. As shown in FIG. 4A, from a top view, the first electrode pad 406 and the second electrode pad 408 may each be in the form of a rectangle with rounded corners. The top view area of the first electrode pad 406 may be greater than, less than, or equal to the top view area of the second electrode pad 408. As shown in FIG. 4A, the top view area of the first electrode pad 406 may be greater than the top view area of the recess C', to ensure that the first electrode pad 406 can fully fill the recess C′. The semiconductor device 4000 may further optionally include a bonding substrate 300 and a bonding structure 302. According to some embodiments, the first contact layer 110c and/or the first capping layer 110a in the semiconductor device 4000 may also be a patterned semiconductor layer, and reference may be made to the relevant descriptions for semiconductor devices 3000A and 3000B. Detailed descriptions regarding the positions, compositions, and materials of the layers or structures in this embodiment have already been provided in the foregoing embodiments and will not be repeated here.

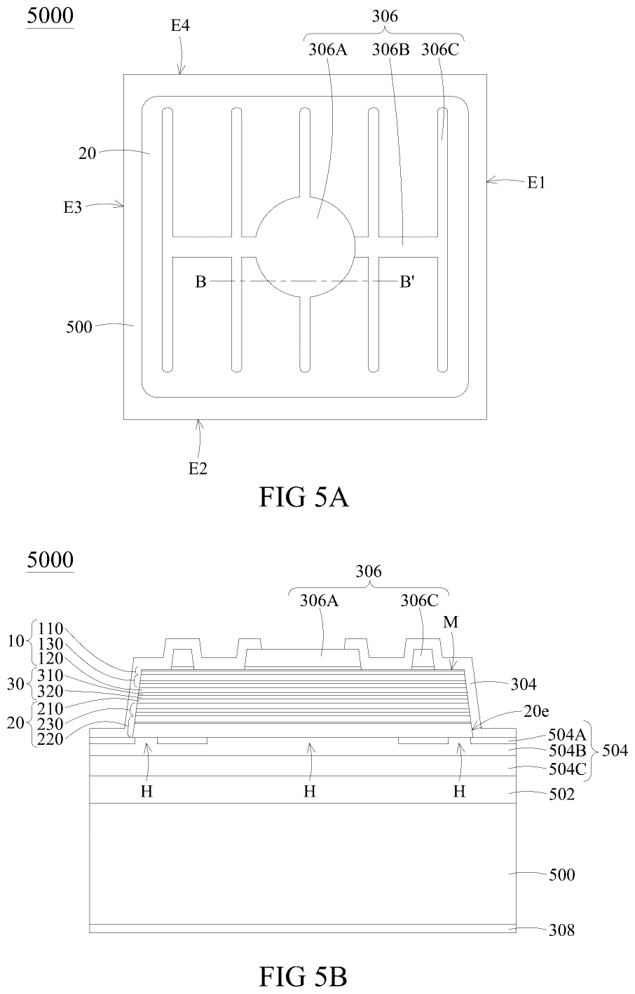

FIG. 5A shows a top view schematic diagram of a semiconductor device 5000 according to some embodiments of the present disclosure. FIG. 5B is a schematic cross-sectional view of the semiconductor device 5000 of FIG. 5A taken along line B-B'. As shown in FIGS. 5A and 5B, the semiconductor device 5000 includes a first epitaxial stack 10, a second epitaxial stack 20, a tunneling structure 30, a bonding substrate 500, a bonding structure 502, a reflective structure 504, a second contact electrode 306, and a first contact electrode 308. As shown in FIGS. 5A and 5B, the second contact electrode 306 may include a main electrode 306A, a first extension electrode 306B, and a plurality of second extension electrodes 306C. The main electrode 306A may serve as an electrical connection point to an external power source or other components, and its shape may be circular. The first extension electrode 306B may extend from the main electrode 306A towards side E1 and side E3 of the semiconductor device 5000, respectively. The plurality of second extension electrodes 306C may be arranged separately and in parallel to each other. In this embodiment, one end of each of the second extension electrodes 306C is connected to the main electrode 306A or the first extension electrode 306B, and the other end extends towards side E2 or side E4 of the semiconductor device 5000.

In this embodiment, the bonding substrate 500 may include a conductive material such as gallium arsenide (GaAs), indium phosphide (InP), silicon carbide (SiC), gallium phosphide (GaP), zinc oxide (ZnO), gallium nitride (GaN), aluminum nitride (AlN), germanium (Ge), or silicon (Si). The bonding substrate 500 may be connected to the reflective structure 504 via the bonding structure 502. The bonding structure 502 may be a single layer or a multilayer (not shown), and may include a conductive material, such as a metal or alloy. Metals may include copper (Cu), aluminum (Al), tin (Sn), gold (Au), indium (In), silver (Ag), lead (Pb), titanium (Ti), nickel (Ni), platinum (Pt), or tungsten (W); or a combination thereof.

The reflective structure 504 may include an insulating layer 504A, a conductive layer 504B, and a reflective layer 504C. The insulating layer 504A is disposed between the conductive layer 504B and the third contact layer 220c. As shown in FIG. 5B, the insulating layer 504A may cover a portion of the third contact layer 220c. In cross-sectional view, the insulating layer 504A may have a plurality of holes H. As shown in FIG. 5B, another portion of the third contact layer 220c, which is not covered by the insulating layer 504A, may be in direct contact with the conductive layer 504B. When the semiconductor device 5000 is in operation, the locations where the third contact layer 220c is in direct contact with the conductive layer 504B may form current paths. In this embodiment, in the vertical direction, the insulating layer 504A may overlap with the first extension electrode 306B and the plurality of second extension electrodes 306C, but not with the main electrode 306A. In other embodiments, in the vertical direction, the insulating layer 504A may also overlap with the main electrode 306A, thereby avoiding current crowding directly beneath the main electrode 306A and facilitating current spreading in the semiconductor device 5000. As shown in FIG. 5B, in the vertical direction, a portion of the insulating layer 504A may overlap with the edge 20e of the second epitaxial stack 20. In some embodiments, the material of the insulating layer 504A may include silicon nitride (SiNx), aluminum oxide (AlOx), silicon oxide (SiOx), magnesium fluoride (MgFx), or combinations thereof.

The conductive layer 504B is disposed between the insulating layer 504A and the reflective layer 504C. In cross-sectional view, the conductive layer 504B may fill the plurality of holes H and be in direct contact with the third contact layer 220c. In some embodiments, the material of the conductive layer 504B may include conductive oxides, such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), indium cerium oxide (ICO), indium tungsten oxide (IWO), indium titanium oxide (ITiO), indium zinc oxide (IZO), indium gallium oxide (IGO), or gallium aluminum zinc oxide (GAZO). The reflective layer 504C is located between the bonding structure 502 and the conductive layer 504B. The reflective layer 504C may include a metal, such as silver (Ag), gold (Au), or aluminum (Al). In this embodiment, as shown in FIG. 5B, the insulating structure 304 may cover the first epitaxial stack 10, the second epitaxial stack 20, the tunneling structure 30, and the reflective structure 504. In this embodiment, the insulating structure 304 may further cover the first extension electrode 306B, the plurality of second extension electrodes 306C, and a portion of the main electrode 306A, exposing only another portion of the main electrode 306A as an electrical connection point to an external power source.

Specifically, the semiconductor device 5000 may be formed by processing the semiconductor epitaxial structure 2000, for example, including the following steps: forming the insulating layer 504A on a portion of the third contact layer 220c; sequentially forming the conductive layer 504B and the reflective layer 504C on the insulating layer 504A; providing the bonding substrate 500 and connecting the bonding substrate 500 to the reflective layer 504C via the bonding structure 502; performing a first etching process to remove the substrate 100 until the first contact layer 110c is exposed; performing a second etching process to define the size of the semiconductor device 5000 and form the platform structure M; separately forming the second contact electrode 306 and the first contact electrode 308; and forming the insulating structure 304. Detailed descriptions regarding the positions, compositions, and materials of the layers or structures in this embodiment have already been provided in the foregoing embodiments and will not be repeated here.

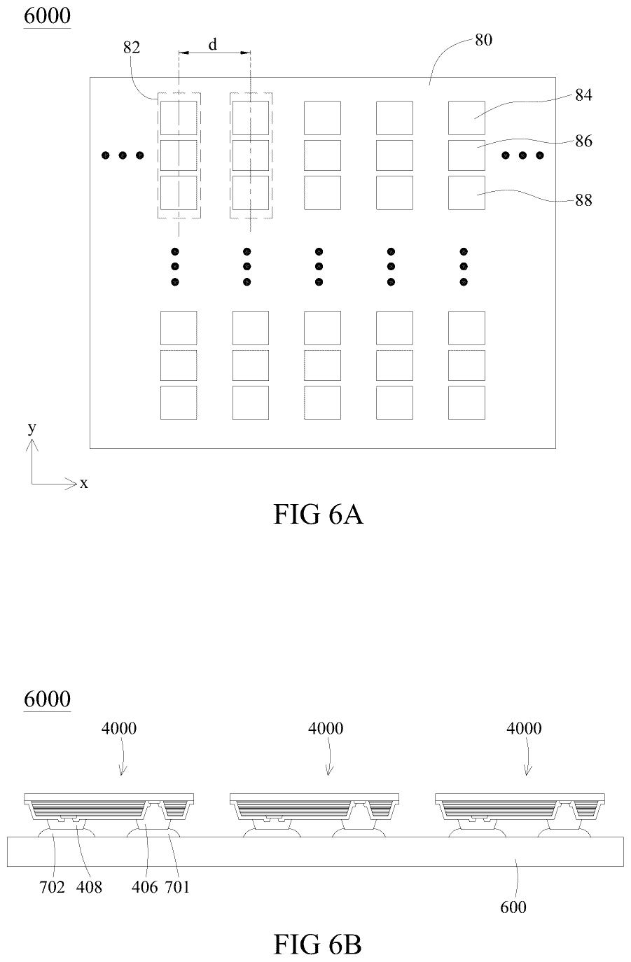

FIG. 6A shows a top view schematic diagram of a semiconductor module 6000 according to some embodiments of the present disclosure. FIG. 6B shows a schematic cross-sectional view of the semiconductor module 6000 according to some embodiments of the present disclosure. In this embodiment, the semiconductor module 6000 is a display device. As shown in FIGS. 6A and 6B, the semiconductor module 6000 includes a carrier substrate 600 and a plurality of pixel units 82 disposed on the carrier substrate 600. The plurality of pixel units 82 may be arranged in an array along directions parallel to the x-axis and y-axis, and are arranged at an interval d in the direction parallel to the x-axis. The number of pixel units 82 may be adjusted as needed; for example, in some embodiments, the plurality of pixel units 82 included in the semiconductor module 6000 may provide a resolution of 1920×1080 pixels. In some embodiments, the interval d is less than 1.4 mm; for example, the interval d is between 0.2 mm and 1.3 mm, specifically 0.75 mm, 0.8 mm, 1 mm, or 1.25 mm. As shown in FIG. 6A, each pixel unit 82 includes a first semiconductor device 84, a second semiconductor device 86, and a third semiconductor device 88 arranged in a direction parallel to the y-axis. One or more of the first semiconductor device 84, the second semiconductor device 86, and the third semiconductor device 88 may be any of the semiconductor devices disclosed in some embodiments herein (such as semiconductor devices 3000A, 3000B, 3000C, 3000D, 4000, or 5000). In FIG. 6B, semiconductor device 4000 is used as an example for illustration. Each semiconductor device 4000 includes a first electrode pad 406 and a second electrode pad 408. The semiconductor module 6000 may further include a plurality of first conductive connection portions 701 and a plurality of second conductive connection portions 702. The first conductive connection portion 701 connects the first electrode pad 406 to the carrier substrate 600, and the second conductive connection portion 702 connects the second electrode pad 408 to the carrier substrate 600. In some embodiments, the first semiconductor device 84, the second semiconductor device 86, and the third semiconductor device 88 are all light-emitting devices and may emit red light, green light, and blue light, respectively. In some embodiments, the arrangement order of these light-emitting devices may also be adjusted as needed; for example, the first semiconductor device 84, the second semiconductor device 86, and the third semiconductor device 88 may emit red light, blue light, and green light, respectively. Each pixel unit 82 may be electrically connected to a conductive structure (not shown) on the surface of the carrier substrate 600, such that the light-emitting devices therein can receive external signals and emit light according to the external signals. In some embodiments, the carrier substrate 600 may be flexible and may withstand a curvature radius of less than 50 mm, such as, 25 mm or 32 mm. The carrier substrate 600 may be a package submount or a printed circuit board (PCB). The carrier substrate 600 may have a single-layer or multi-layer structure. The material of the carrier substrate 600 may include polyester, polyimide (PI), BT resin (Bismaleimide Triazine), PTFE resin (Polytetrafluoroethylene), phenol resins (PF), or glass fiber epoxy resin. The materials of the first conductive connection portion 701 and the second conductive connection portion 702 may include metals, such as tin (Sn). Detailed descriptions regarding the positions, relative relationships, material compositions, and structural variations of the other layers or structures in this embodiment have already been provided in the foregoing embodiments and will not be repeated here.

In summary, according to embodiments of the present disclosure, a semiconductor epitaxial structure, a semiconductor device, and a semiconductor module are provided. By adopting the design of the above-mentioned epitaxial structure and/or device structure, the optoelectronic characteristics of the device can be improved. For example, by adjusting the thickness and/or the aluminum content percentage of the first capping layer, the light emission intensity can be effectively enhanced, and the light emission efficiency can be improved; by providing two or more light-emitting stacks in combination with an improved tunneling structure, the brightness performance can be further enhanced, and the cost per unit brightness can be effectively reduced. In addition, the embodiments of the present disclosure are applicable to products requiring miniaturization. Specifically, the semiconductor epitaxial structure, semiconductor device, and semiconductor module of the present disclosure can be applied to products in the fields of lighting, display, communication, power systems, and the like, such as lamps, monitors, automotive dashboards, televisions, computers, traffic signals, and outdoor displays.

While the present invention has been disclosed above by way of exemplary embodiments, various modifications or changes may be made without departing from the spirit and scope of the present invention. Therefore, the scope of protection of the present invention shall be defined by the appended claims. The contents of the above embodiments may be combined or substituted with each other where and are not limited to the specific embodiments described. For example, in some embodiments, the parameters related to specific components or the connection relationships between specific components and other components as disclosed may also be applied to other embodiments, all of which fall within the scope of protection of the present invention.

1. A semiconductor device, comprising:
a first epitaxial stack, comprising
a first semiconductor structure, comprising a first capping layer having a first thickness;
a second semiconductor structure, comprising a second capping layer having a second thickness; and
a first active region disposed between the first semiconductor structure and the second semiconductor structure, the first active region comprising a light-emitting stack, a first confinement structure located between the light-emitting stack and the first capping layer, and a second confinement structure located between the light-emitting stack and the second capping layer, wherein the first confinement structure has a third thickness and the second confinement has a fourth thickness; and
a first contact electrode, electrically connecting the first semiconductor structure;
wherein the first thickness is smaller than the second thickness, and the third thickness is larger than the fourth thickness.

2. The semiconductor device according to claim 1, wherein the second thickness is larger than the fourth thickness.

3. The semiconductor device according to claim 1, wherein the third thickness is in a range of 1000 Å to 3000 Å.

4. The semiconductor device according to claim 1, wherein the first epitaxial stack has a thickness in a range of 1 μm to 5 μm.

5. The semiconductor device according to claim 1, wherein the first capping layer comprises aluminum, and has an aluminum content percentage in a range of 54% to 60%.

6. The semiconductor device according to claim 1, wherein the first capping layer and the second capping layer comprise aluminum, and the first capping layer has an aluminum content percentage larger than that of the second capping later.

7. The semiconductor device according to claim 1, wherein the first capping layer comprises a first dopant, and the first dopant in the first capping layer has a concentration in a range of 1×1017cm−3 to 2×1018 cm−3.

8. The semiconductor device according to claim 7, wherein the first semiconductor structure further comprising a first contact layer, and the first contact layer has a second dopant different from the first dopant.

9. The semiconductor device according to claim 8, wherein the second dopant in the first contact layer has a concentration larger than that of the first dopant in the first capping layer.

10. The semiconductor device according to claim 8, wherein the first contact layer has a width smaller than that of the first capping layer.

11. The semiconductor device according to claim 8, wherein the first semiconductor structure further comprising a first transition structure located between the first capping layer and the first contact layer, and the first transition structure comprises a material different from that of the first capping and the first contact layer.

12. The semiconductor device according to claim 11, wherein the first capping layer comprises AlInP, and the first transition structure comprises AlGaInP.

13. The semiconductor device according to claim 1, further comprising a bonding substrate disposed below the first epitaxial structure and a bonding structure disposed between the bonding structure and the first semiconductor epitaxial structure.

14. The semiconductor device according to claim 1, further comprising an insulating structure covering the first epitaxial stack.

15. The semiconductor device according to claim 1, wherein the first confinement structure comprises a first sublayer and a second sublayer, the first sublayer is located between the light-emitting stack and the second sublayer and has a thickness smaller than that of the second sublayer.

16. The semiconductor device according to claim 15, wherein the first sublayer and the second sublayer comprise different materials.

17. The semiconductor device according to claim 15, wherein the first sublayer and the second sublayer comprise aluminum, and the first sublayer has an aluminum content percentage smaller than that of the second sublayer.

18. The semiconductor device according to claim 1, further comprising a second epitaxial structure located on the first epitaxial structure, wherein the second epitaxial structure a third semiconductor structure, a fourth semiconductor structure and a second active region located between the third semiconductor structure and the fourth semiconductor structure.

19. The semiconductor device according to claim 18, further comprising a tunneling structure dispose between the first epitaxial structure and the second epitaxial structure.

20. A semiconductor module, comprising:
a carrier substrate; and
a plurality of the semiconductor devices of claim 1 disposed on the carrier substrate and arranged in an array.
